(19) United States
(12) Patent Application Publication
(10) Pub. No.: US 2006/0030114 A1
(43) Pub. Date: Feb. 9, 2006

(54) METHOD FOR FORMING JUNCTION VARACTOR AND APPARATUS THEREOF

(76) Inventors: Ta-Hsun Yeh, Hsin-Chu City (TW); Yuh-Sheng Jean, Yun-Lin Hsien (TW)

Correspondence Address: NORTH AMERICA INTELLECTUAL PROPERTY CORPORATION, P.O. BOX 506, MERRIFIELD, VA, 22116, US

(21) Appl. No.: 11/161,397

(22) Filed: Aug. 2, 2005

(30) Foreign Application Priority Data
Aug. 4, 2004 (TW) 093123380

(51) Int. Cl. H01L 21/20; H01L 21/8238; H01L 21/331

(52) U.S. Cl. 438/379; 438/202; 438/224; 438/309

(57) ABSTRACT

A method for forming a junction varactor and apparatus thereof are disclosed. The method includes: forming at least one deep N-well in a P-type substrate; forming a P-well in the deep N-well; forming at least one n⁺ region in the P-well; and performing a contact process to couple the n⁺ region and the deep N-well to an anode, and to couple the P-well to a cathode.

### BACKGROUND OF THE INVENTION

1. Field of the Invention

The present invention discloses a junction varactor, especially a method for forming the junction varactor and apparatus thereof.

2. Description of the Prior Art

A junction varactor is generally used for supplying reverse bias voltage because its electric current abruptly increases easily when a forward bias voltage is applied thereon. When a reverse bias voltage is applied thereon, it not only exhibits high reverse resistance but also the so-called transition capacitance. Therefore, through adjustment the magnitude of the reverse bias voltage, the amount of the transition capacitance can be controlled to achieve the purpose of capacitance variation. Due to the above-mentioned characteristics, the junction varactor has been extensively applied for voltage-controlled oscillators and tunable filters in the analog/RF IC design field.

Referring to FIG. 1 and 2, a junction varactor manufactured according to conventional technique is shown. The conventional manufacturing method comprises providing a P-type substrate 12; forming an N-well 14 in the P-type substrate 12; forming a p⁺ region 16 and an n⁺ region 18 in the N-well 14; and forming another p⁺ region 22 in the P-type substrate 12.

When there is no bias voltage applied between the anode and the cathode (that is between the p⁺ region 16 and the n⁺ region 18), in order to satisfy the state of thermal equilibrium, the net electric current resulting from electrons and electric holes passing through the PN junction constituted by the p⁺ region 16 and the N-well 14 is zero, from which deduction that Fermi energy level must be a constant can be derived. The Fermi energy level under the state of thermal equilibrium leads to a unique space charge distribution in the PN junction and thus results in a depletion region 24, as shown in FIG. 2, wherein the depletion region has a width W.

Referring to FIG. 3, when a reverse bias voltage (V_{R}) is applied between the anode and the cathode, the width W of the depletion region 24 is increased since the electrostatic potential across the PN junction is increased. Moreover, the space charge distribution and the electric field distribution of the depletion region 24 are increased accordingly, leading to a change in the unit capacitance of the junction capacitance (that is the capacitance of the depletion region). The relationship between the unit capacitance of the junction capacitance and the reverse bias voltage is expressed as follows:
Cⱼ α(V_{bi}+V_{R})⁻ⁿ (EQ-1)

wherein V_{bi} is the build-in voltage which is the electrostatic potential across the PN junction under thermal equilibrium and only depends on acceptor impurity density, donor impurity density and intrinsic density, and thus can be regarded as a constant, and n can be different values according to the type of PN junction employed. However, it is apparent, as seen in EQ-1, that the unit capacitance of the junction capacitance is changed accordingly if the reverse bias voltage is adjusted. It means that the capacitance value of the junction capacitance is also changed accordingly so as to achieve the purpose of capacitance variation.

Referring to FIG. 4, it is an equivalent circuit drawing of the junction varactor 10 of FIG. 3. Referring to FIG. 3 and FIG. 4, there are a varactor diode 26 and a series resistor 28 connected with the varactor diode 26 in a series fashion disposed between the anode and the cathode of the junction varactor 10. The varactor diode 26 comprises the p⁺ region 16 and the N-well 14 and achieves the purpose of capacitance variation by the depletion behavior of the PN junction comprising the p⁺ region 16 and the N-well 14. As a matter of fact, there is an equivalent parallel resistor 32 connected with the varactor diode 26 in a parallel fashion between the anode and the cathode of the varactor diode 26, wherein the equivalent parallel resistor 32 is derived from effects such as generation-recombination current, diffusion current, surface leakage current, etc. In general, the junction capacitance and the resistance of series resistor 28 are decreased with the increase of the reverse bias voltage, while the resistance of the equivalent parallel resistor 32 is increased with the increase of applied voltage.

Nevertheless, there are limitations for the conventional junction varactor 10. For the general application of the junction varactor 10, specifications including tuning range, linearity and unit capacitance are important in terms of the selection of junction varactor 10, wherein the unit capacitance is defined as charge stored per unit area per unit voltage, the linearity is defined as the degree of deviating from the linear relationship, and the tuning range is defined as the ratio (Cₘₐₓ/Cₘᵢₙ) of the maximum unit capacitance (Cₘₐₓ) to the minimum unit capacitance (Cₘᵢₙ). The implant concentration and the implant depth of the p⁺ region 16 and the N-well 14 are the primary factors determining these characteristics. Because different implant concentrations and implant depths result in different PN junctions and thus different depletion behaviors, and finally different capacitance-voltage relationships are obtained. For example, referring to FIG. 5, there are the junction capacitance-reverse bias voltage curves of the junction varactor 10, manufactured by conventional technique, under different PN junctions. As shown in FIG. 5, if the PN junction formed by the p⁺ region 16 and the N-well 14 (referring to FIG. 3 also) is a hyperabrupt junction, the resultant junction capacitance is higher than that of an abrupt junction. Likewise, among various PN junctions, the unit capacitance of the hyperabrupt junction is the highest and the unit capacitance of the linear slope junction is the lowest.

Some corresponding information is disclosed in Chapter 2, “Physics of semiconductor devices” second edition, 1981, S. M. Sze.

The implant concentration and the implant depth of the p⁺ region 16 and the N-well 14 have to be increased if the unit capacitance is to be increased. That is to say, the implant concentration is increased to reduce the width W of the depletion region 24 in FIG. 3. This is not a preferable solution as an increase in carrier density results in problems such as an increase in leakage current, reduced junction breakdown voltage, etc.

### SUMMARY OF THE INVENTION

One of objectives of the invention is to provide a junction varactor to solve the above-mentioned problems.

One of objectives of the invention is to provide a junction varactor which has high unit capacitance.

One of objectives of the invention is to provide a junction varactor which has good linearity.

One of objectives of the invention is to provide a junction varactor which has no influence on leakage current and breakdown voltage.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1, 2, and 3 are cross-sectional drawings of the conventional junction varactor.

FIG. 4 is an equivalent circuit drawing of the conventional junction varactor of FIG. 3.

FIG. 5 is a junction capacitance-reverse bias voltage curve plot of the conventional junction varactor, under different PN junctions.

FIG. 6 and 7 are cross-sectional drawings of the junction varactor according to the first embodiment of the invention.

FIG. 8 is a layout drawing of the junction varactor of FIG. 7.

FIG. 9 is an equivalent circuit drawing of the junction varactor of FIG. 7.

FIG. 10 is a junction capacitance-reverse bias voltage curve plot of the junction varactor of the invention and the conventional junction varactor.

FIG. 11 and 12 are cross-sectional drawings of the junction varactor according to the second embodiment of the invention.

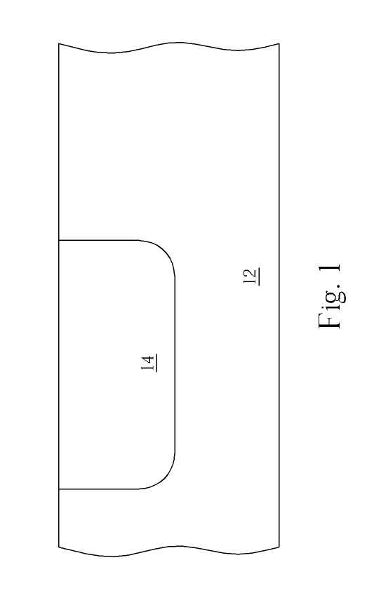

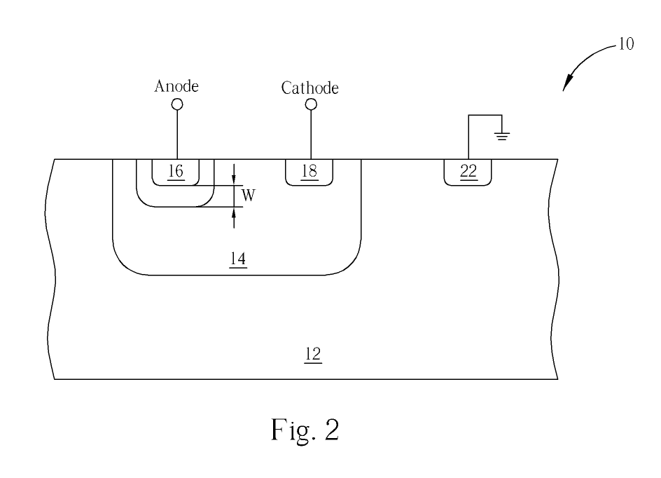

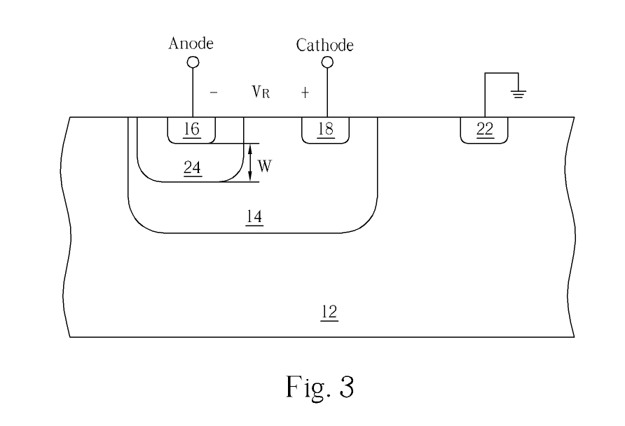

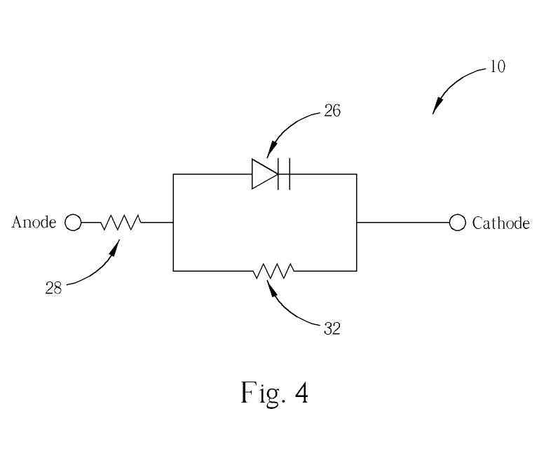

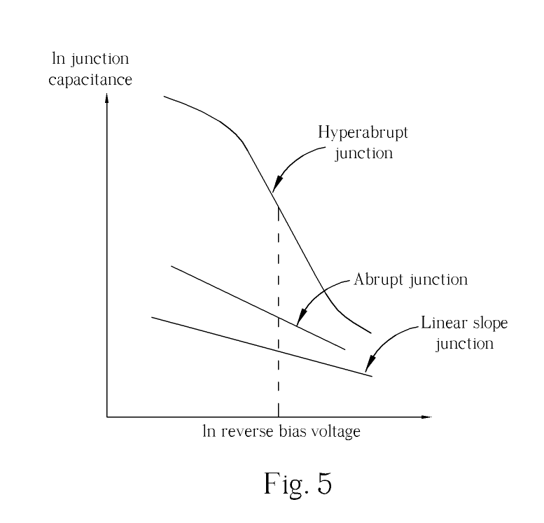

### DETAILED DESCRIPTION

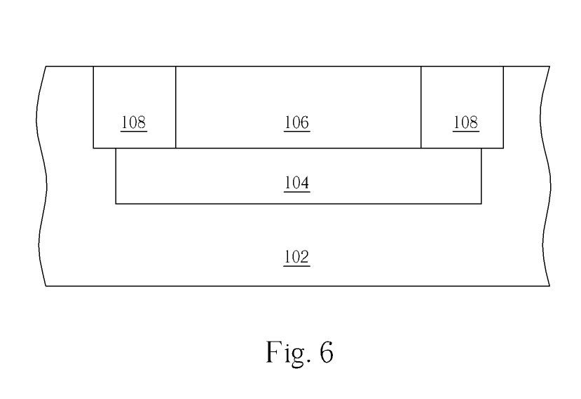

As shown in FIG. 6, according to the invention, the manufacturing method of the junction varactor 100 comprises: providing a P-type substrate 102 which is used as base material; using a triple-well process to form a deep N-well 104 in the P-type substrate 102 and a P-well 106 in the deep N-well 104, wherein the P-well 106 is surrounded by an N-well 108. In fact, the deep N-well 104, the P-well 106 and the N-well 108 are manufactured by using masks previously designed and various ion implant processes.

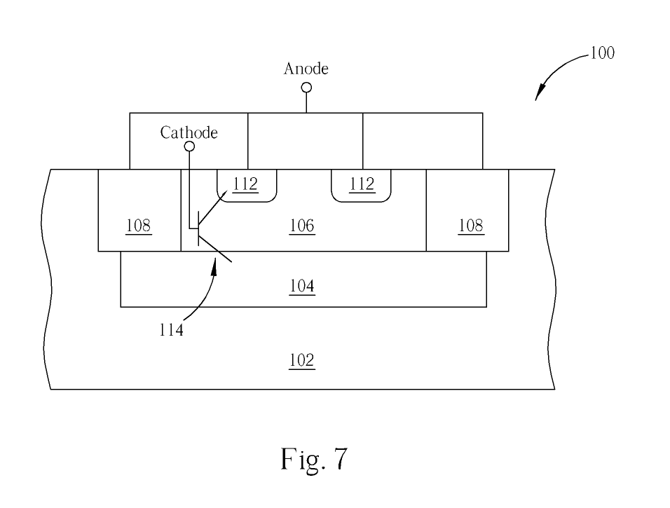

As shown in FIG. 7, then, at least one n⁺ region 112 is formed in the P-well 106 to form a triple-well structure. In FIG. 7, the example of forming two n⁺ regions 112 is given. Therefore, each set of the n⁺ region 112, the P-well 106 and the deep N-well 104 forms a longitudinal parasitic NPN bipolar-junction transistor (NPN BJT) 114, wherein the deep N-well 112 is an emitter, the P-well 106 is a base and the deep N-well 104 is a collector. Subsequently, a contact process is carried out to form at least one dielectric layer (not shown) and at least one contact hole (not shown) on the surface of the P-type substrate 102 to electrically connect the each n⁺ region 112 and deep N-well 104 to the anode and P-well 106 to the cathode so as to complete the junction varactor 100. It is noteworthy that the purpose of electrically connecting the deep N-well 104 to the anode is achieved by electrically connecting the N-well 108 to the anode because the N-well 108 not only surrounds the P-well 106 but also directly contacts the deep N-well 104.

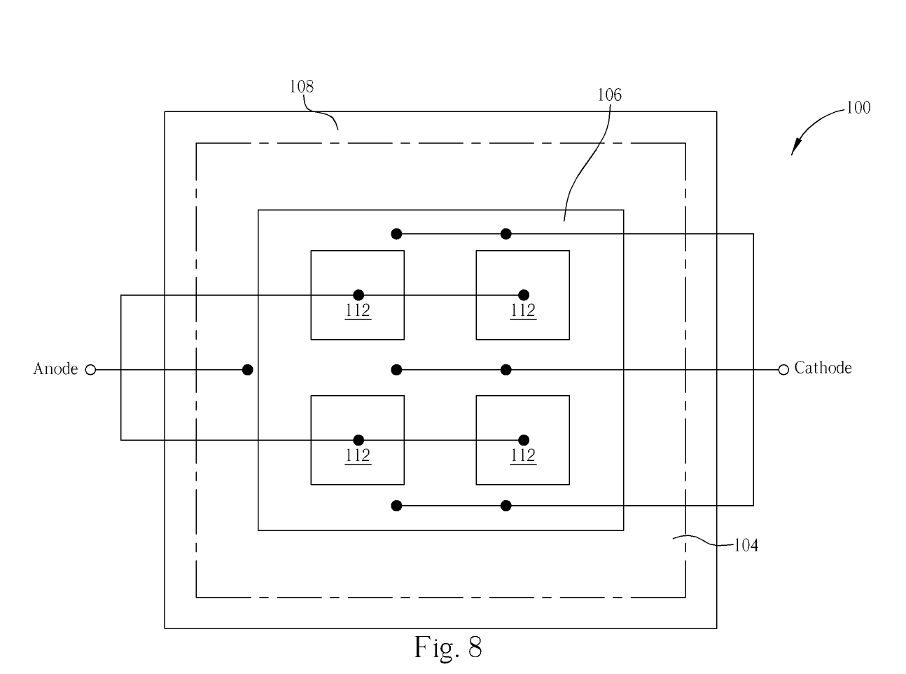

Referring to FIG. 8, a schematic drawing of the layout of the junction varactor 100 in FIG. 7 is presented. As shown in FIG. 8, the invented junction varactor 100 is manufactured on the P-type substrate (not shown), the deep N-well 104 is disposed in the P-type substrate (not shown), the P-well 106 is disposed in the deep N-well 104 and a plurality of the n⁺ regions 112 are disposed in the P-well 106. The P-well 106 is surrounded by the N-well 108 and the N-well 108 has direct contact with the N-well 104. Each set of the n⁺ region 112, the P-well 106 and the deep N-well 104 forms a longitudinal parasitic NPN bipolar-junction transistor 114 (referring to FIG. 7 also). Meanwhile, each n³⁰ region 112 and N-well 108 is electrically connected to the anode, while the P-well 106 adjacent to each n⁺ region 112 is electrically connected to the cathode.

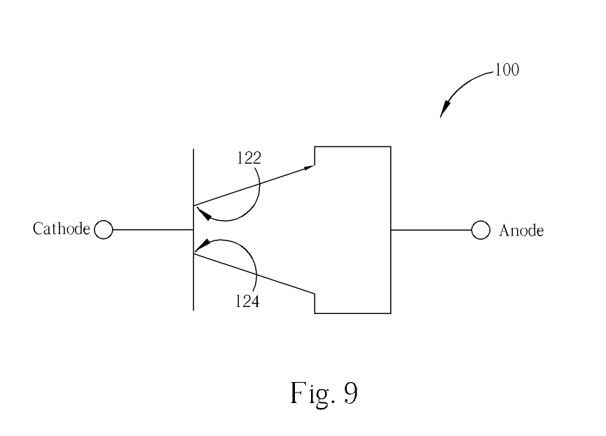

FIG. 9 shows an equivalent circuit deawing of the junction varactor 100 of FIG. 7. As shown in FIG. 9, each invented junction varactor 100 can be regarded as an equivalent capacitor of paralleling a first junction capacitor 122 and a second junction capacitor 124. Referring to FIG. 7 also, the first junction capacitor is located at the PN junction comprising the n⁺ region 112 (emitter) and the P-well 106 (base) and the second junction capacitor is located at the PN junction comprising P-well 106 (base) and the deep N-well 104 (collector). Because each junction varactor 100 is an equivalent capacitor of paralleling the first junction capacitor 122 and the second junction capacitor 124, the unit capacitance C of each junction varactor 100 and the unit capacitance Cⱼ₁ and Cⱼ₂ of the first junction capacitor 122 and the second junction capacitor 124, respectively, satisfy the following relationship
C=Cⱼ₁+Cⱼ₂ (EQ-2)

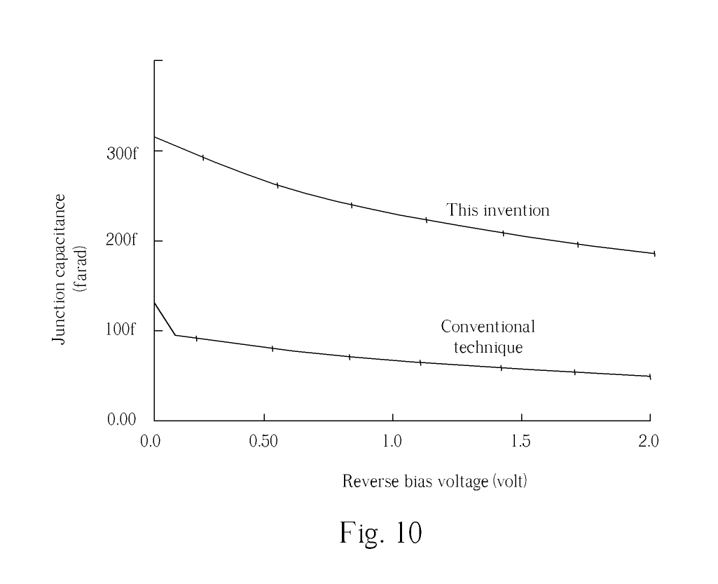

According to EQ-2, if a unit of reverse bias voltage is applied to each junction varactor 100, the unit capacitance is equal to the sum of the unit capacitance of the first junction capacitor 122 and the second junction capacitor 124. Therefore, the unit capacitance of the junction varactor 100 can be effectively increased. Referring to FIG. 10, junction capacitance-reverse bias voltage curves of the junction varactor 100 manufactured by the invented method and the junction varactor 10 manufactured by conventional technique are provided. As shown in FIG. 10, when comparison of the junction capacitance-reverse bias voltage curves of the junction varactor 100 manufactured by the invented method and the junction varactor 10 manufactured by conventional technique are made and both have surface area of 10 μm×10 μm, it is found that the junction varactor 100 manufactured by the invented method apparently has higher total capacitance and its linearity and tuning range are not inferior to those of the junction varactor 10 manufactured by conventional technique.

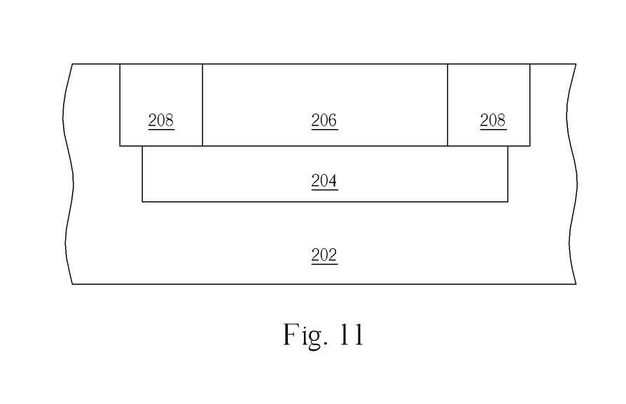

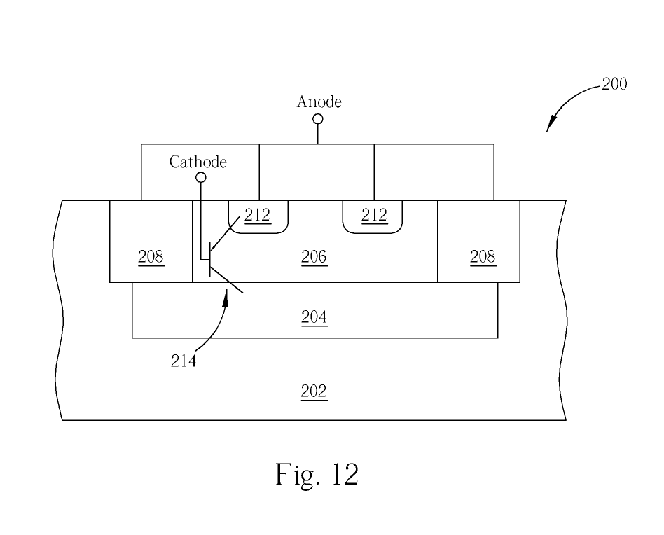

The above-mentioned example depicts the method of manufacturing the parasitic NPN bipolar-junction transistor by using the triple-well process. Moreover, the invented manufacturing method can also be used for forming a parasitic PNP bipolar-junction transistor on an N-type substrate to form a junction varactor. Referring to FIG. 11 and FIG. 12, cross-sectional drawings of at least one junction varactor 200 according to the second example of the invention are given. As shown in FIG. 11, the manufacturing method of the junction varactor 200 comprises providing an N-type substrate 202 which is used as base material, performing a triple-well process to forming at least one deep P-well 204 in the N-type substrate 202 and an N-well 206 in the deep P-well 204, wherein the N-well 206 is surrounded by a P-well 208. In practice, the deep P-well 204, the N-well 206 and the P-well 208 are manufactured by using masks previously designed and various ion implant processes.

As shown in FIG. 12, then, at least one p⁺ region 212 is formed in the N-well 206 to form a triple-well structure. In FIG. 12, the example of forming two p⁺ regions 212 is given. Therefore, each set of the p⁺ region 212, the N-well 206 and the deep P-well 204 forms a longitudinal parasitic PNP bipolar-junction transistor (PNP BJT) 214, wherein the deep P-well 212 is an emitter, the N-well 206 is a base and the deep P-well 204 is a collector. Subsequently, a contact process is carried out to form at least one dielectric layer (not shown) and at least one contact hole (not shown) on the surface of the N-type substrate 202 to electrically connect the each p⁺ region 212 and deep P-well 204 to the anode and the N-well 206 to the cathode so as to complete the junction varactor 200. The purpose of electrically connecting the deep P-well 204 to the anode is achieved by electrically connecting the P-well 208 to the anode because the P-well 208 not only surrounds the N-well 206 but also directly contacts the deep P-well 204.

The triple-well process employed in the invention to manufacture the junction varactors 100, 200 can also be integrated with the conventional CMOS process to become a CMOS triple-well process. When the junction varactor 100 or the junction varactor 200 is formed, CMOS is simultaneously formed on a P-type substrate 102 or an N-type substrate 202, wherein the formed CMOS thereby comprises an N-type triple-well MOS or a P-type triple-well MOS.

In the embodiment, this invention utilizes a triple-well process to form a longitudinal parasitic bipolar-junction transistor and electrical connection to parallel two junction capacitors to form a junction varactor, the unit capacitance of the junction varactor can be effectively increased with the original linearity and tuning range retained and there are no issues of increased leakage current or reduced breakdown voltage derived.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of manufacturing at least one junction varactor, the method comprising:
forming at least one deep N-well in a P-type substrate;
forming a P-well in the deep N-well;
forming at least one n⁺ region in the P-well; and
performing a contact process to couple the n⁺ region and the deep N-well to an anode, and to couple the P-well to a cathode.

2. The method of claim 1, wherein the n⁺ region and the P-well form a first junction capacitor, and the P-well and the deep N-well form a second junction capacitor.

3. The method of claim 2, wherein the unit capacitance of the junction varactor is corresponding to an equivalent unit capacitance of paralleling the first and the second junction capacitors.

4. The method of claim 1, wherein the n⁺ region, the P-well, and the deep N-well form a longitudinal NPN bipolar-junction transistor.

5. The method of claim 4, wherein the longitudinal NPN bipolar-junction transistor is a parasitic bipolar-junction transistor.

6. The method of claim 1, wherein the P-well is surrounded by at least one N-well and the N-well has contact with the deep N-well.

7. The method of claim 6, wherein the N-well is coupled to the anode.

8. The method of claim 1, wherein the triple-well process is a CMOS triple-well process.

9. A method of manufacturing at least one junction varactor, the method comprising:
performing a tripe-well process to form at least one doped-well of a second conductive type in a first conductive type substrate, a second doped-well of the first conductive type in the first doped-well and at least one heavily doped-well region of the second conductive type in the second doped-well; and
performing a contact process to couple the heavily doped-well region and the first doped-well to an anode and to couple the second doped-well to a cathode.

10. The method of claim 9, wherein the heavily doped-well region, the second doped-well and the first doped-well form a longitudinal bipolar-junction transistor.

11. The method of claim 10, wherein the first conductive type is an N-type, the second conductive type is a P-type and the longitudinal bipolar-junction transistor is a parasitic PNP bipolar-junction transistor.

12. The method of claim 10, wherein the first conductive type is a P-type, the second conductive type is an N-type and the longitudinal bipolar-junction transistor is a parasitic NPN bipolar-junction transistor.

13. The method of claim 9, wherein the heavily doped-well region and the second doped-well form a first junction capacitor, and the second doped-well and the first doped-well form a second junction capacitor.

14. The method of claim 13, wherein the unit capacitance of the junction varactor is corresponding to an equivalent unit capacitance of paralleling the first and the second junction capacitors.

15. The method of claim 9, wherein the second doped-well is surrounded by at least one third doped-well of a second conductive type and the third doped-well has contact with the first doped-well.

16. The method of claim 9, wherein the third doped-well is coupled to an anode.

17. The method of claim 9, wherein the triple-well process is a CMOS triple-well process.

18. A varactor, comprising:
a first conductive type substrate;
at least one first doped-well of a second conductive type in the first conductive type substrate;
a second doped-well of the first conductive type in the at least one first doped-well; and
at least one heavily doped-well region of the second conductive type in the second doped-well;
wherein the heavily doped-well region and the first doped-well are coupled to an anode, and the second doped-well is coupled to a cathode.

19. The varactor of claim 18,
wherein the heavily doped-well region and the second doped-well form a first junction capacitor, and the second doped-well and the first doped-well form a second junction capacitor,
wherein the unit capacitance of the varactor is corresponding to an equivalent unit capacitance of paralleling the first and the second junction capacitors.

20. The varactor of claim 18, wherein the heavily doped-well region, the second doped-well and the first doped-well form a longitudinal bipolar-junction transistor.
